(19) United States
(12) Patent Application Publication
(10) Pub. No.: US 2010/0096708 A1
(43) Pub. Date: Apr. 22, 2010

(54) Chip Module for Installing in Sensor Chip Cards for Fluidic Applications and Method for Producing a Chip Module of This Type

(76) Inventor: Gerald Eckstein, Munchen (DE)

Correspondence Address: STAAS & HALSEY LLP, SUITE 700, 1201 NEW YORK AVENUE, N.W., WASHINGTON, DC, 20005, US

(21) Appl. No.: 11/989,939

(22) PCT Filed: Jun. 21, 2006
(86) PCT No.: PCT/EP2006/063402

§ 371 Date: Feb. 4, 2008

(30) Foreign Application Priority Data
Aug. 4, 2005 (DE) 10 2005 036 824.7

(51) Int. Cl. H01L 23/48; H01L 21/50

(52) U.S. Cl. 257/414; 438/48; 257/690; 438/121; 257/E23.01; 257/E21.499

(57) ABSTRACT

A plate-shaped chip supporting body has a number of write/read contacts for exchanging data with an external chip card. A number of corresponding terminal panels which are electrically connected to the write/read contacts of the front flat side, are arranged on the opposite rear side of the chip supporting body. A sensor ship is attached to the rear side of the chip supporting body and has contact pads electrically connected to the terminal panels of the chip supporting body. Contact panels on the flat side of the sensor chip are oriented toward the chip supporting body and are connected to the pad contact, which are located on the opposite flat side of the sensor chip, by at least one electrical signal line path passing through the sensor chip, and the contact panels are connected to the terminal panels of the chip supporting body by electrically conductive material.

### CROSS REFERENCE TO RELATED APPLICATIONS

This application is based on and hereby claims priority to German Application No. 10 2005 036 824.7 filed on Aug. 4, 2005, the contents of which are hereby incorporated by reference.

### BACKGROUND

Described below is a chip module for installing in sensor chip cards for fluidic applications, having plate-shaped chip supporting body on which, oriented towards the front flat edge of the outside of the sensor chip card, are arranged a plurality of write/read contacts for data exchange with external chip card reader devices, and on the opposite rear side of which are arranged a plurality of electrically connected terminal panels corresponding to the write/read contacts of the front flat side, and a sensor chip attached to the rear of the chip supporting body, which features contact pads which are electrically connected to the terminal panels of the chip supporting body. In addition a method is described for producing a chip card with the above-mentioned category-defining features.

Chip modules of the type described above for installing in sensor chip cards for fluidic applications are known from the related art in different embodiments and have to date been produced in a classical fabrication and connection technology such that, for the electrical connection between the contact pads present on the sensor chip with the terminal panels located on the chip supporting body, the technique known as wire bonding has been used. This technique make provision for wiring in the form of a wire bridge formed by a thin wire to be established between the components to be connected, which is sealed in a further production step, for example by using Globtop encapsulation. The diameter of the wires used makes it necessary with this connection technology for specific wire radii to be adhered to in order to prevent the wires being broken. For these reasons the encapsulation surrounding the wiring in the form of a bump, which effects both a mechanical and also an electrochemical protection in relation to the effects of corrosion, is prone to the disadvantage that the total height of the chip module is not inconsiderably higher than the actual joint installation height of sensor chip and chip supporting body.

In addition the dome-like covering of the bond wires leads to a diminution of the sensor surface present on the rear of the sensor chip, with care having to be taken that an additional sealing ring for fluid sealing must be applied surrounding the sensor surface.

An enlargement of the sensor surface of the sensor chip as a result of special operating requirements thus makes an enlargement of the entire chip necessary, on the other hand with a predetermined reduction of the installation height of the chip module a reduction in the maximum active sensor surface is inevitable.

Furthermore with the chip modules known from the related art described above there is the disadvantage that the encapsulation domes inevitably protrude beyond the actual outer active sensor surface of the sensor chip. This fact prevents a physical and/or chemical cleaning of the sensor surface.

In addition it should be stated that the bond technique applied from the related art for this type of chip module, although it has been proven in practice, makes an expensive process optimization of the wire bond height necessary as regards the production process. Furthermore the precise arrangement of the fluid sealing in the form of the seal surrounding the active sensor surface of the sensor chip by a sealing ring involves expense in production, since in respect of contaminants and possible covering of the sensor surface the greatest attention must be paid to the arrangement of the seal.

Using as its starting point the aforementioned disadvantages in the known design of such a chip module, it is thus an aspect of the chip module described herein to provide for installation in sensor chip cards for fluidic applications, in which the required installation height can be reduced without at the same time reducing the active sensor surface of the sensor chip or in which an enlargement of the active sensor surface can be produced while the installation height remains the same. In addition the chip module should be able to be produced cost effectively through reduced production effort.

The chip module may be produced by an innovative method to have a reduction in production costs and also to obtain the improvements described above in relation to installation height and sensor surface dimensions.

The significant teaching in respect of the embodiment of the chip module makes provision in this case for contact panels to be arranged on the flat side of the sensor chip oriented towards the chip supporting body, which are each connected by contact pads located on the opposite flat side of the sensor chip by at least one electrical signal line path leading through the sensor chip and for the contact panels to be connected to the terminal panels of the chip supporting body by electrically-conductive material.

The innovative connection technique used for the chip module makes both the expensive bond wiring and the associated application of an encapsulation dome to known chip modules for fluidic applications superfluous. The installation height of the newly conceived contact panels on the sensor chip can be kept extremely small in this case, allowing the overall installation height of the chip module to be significantly reduced. In addition the active sensor surface of the sensor chip can be significantly enlarged because the encapsulation dome of the bond wires has now been dispensed with since the fluidic linkage of the sensor chip can also be simplified.

### SUMMARY

In accordance with an advantageous development of the subject matter, it has proved advantageous in respect of the chip module to construct the signal line paths from an electrically-conductive inner path and a sheathing or coating surrounding the path made up of electrically-isolating material. This embodiment can be produced at low cost and offers a guarantee of a reliable electrical connection between the pad contacts provided with the active sensor surface and the contact panels present on the opposing flat side.

The embodiment of the electrically-conducting inner path can in this case, depending on the cross-sectional requirement, may be an annular cross section or an essentially round full cross section. The sheathing surrounding the electrically-conductive inner-path of the signal line path is preferably constructed by using a dielectric, with the nitrite and oxide compounds being able to be used.

The electrically-conductive material for connecting the contact panels of the sensor chip to the corresponding terminal panels of the chip supporting body can be produced using a conductive adhesive if required or by a metallic solder connection. To attach a sensor chip to a chip supporting body an underfiller in the remaining space between the surfaces of sensor chip and chip supporting body facing each other ensures that the entire installation unit of the chip module is also able to withstand increased mechanical loads.

The significant teaching of the method makes provision in this case, prior to attachment of the sensor chip on the chip supporting body, for cutouts to be made using an anisotropic etching process running from one flat side to the other flat side for signal line paths, subsequently for the surface areas of the cutouts to be coated with an electrically-isolating material and then with an electrically-conductive material, thereafter the contact surfaces or panels to be applied to the flat side of the sensor chip provided for attachment to the chip supporting body and after the placing of the sensor chip on the chip supporting body, for the electrical connection between the contact surfaces of the sensor chip and the connecting surfaces or terminal panels of the chip supporting body to be established.

The signal line path can be implemented at low cost, with the conceived signal line path making the previously normal bond technique for electrical connection of the contact pads of the sensor chip to the terminal surfaces of the chip module superfluous, whereby the installation height of the chip module is simultaneously reduced or, if necessary through the omission of the encapsulation dome or the bond wires, the active sensor surface of the sensor chip can be significantly increased.

The method for producing the coating surrounding the electrically-conductive inner track of the signal line can in this case be undertaken using a dielectric as material.

In addition it has proved to be advantageous to establish the electrical connection between the contact surfaces of the sensor chip and the terminal surfaces of the chip supporting body by using a soldering process, since this can be carried out at low cost.

Another cost effective option of implementing the electrical connection between the contact surfaces of the sensor chip and the terminal surfaces of the chip supporting body is represented by the use of a conductive adhesive which is introduced between the facing surfaces of the contact surfaces and terminal surfaces. The use of a conductive adhesive additionally has the advantage of allowing the sensor chip to be attached to the chip supporting body at the same time.

In the application cases in which as a result of increased mechanical load for example with the use of a conductive adhesive as the electrical connection, an additional fixing of the sensor chip on the chip supporting body is necessary, after the establishment of the electrical connection between the contact surfaces of the sensor chip and the terminal surfaces of the chip supporting body, the remaining space between the surfaces facing one another of sensor chip and chip supporting body can be filled with an underfiller.

Explained in greater detail below are the chip module and a method of producing with reference to two exemplary embodiments, with only the features necessary for the understanding being shown in the drawings.

### BRIEF DESCRIPTION OF THE DRAWINGS

These and other aspects and advantages will become more apparent and more readily appreciated from the following description of the exemplary embodiments, taken in conjunction with the accompanying drawings of which

FIG. 1 is an overhead view of a chip module;

FIG. 2 is a cross-sectional view through the chip module corresponding to the line B-B from FIG. 1;

FIGS. 3A-3F are cross-sectional views of a sequence of production steps of the method for producing a chip module corresponding to FIGS. 1 and 2;

FIG. 4 is a view from below corresponding to arrow C from FIG. 3f of the completed chip sensor;

FIG. 5 is a cross-sectional view through a further embodiment variant of the chip module corresponding to the diagram shown in FIG. 4.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

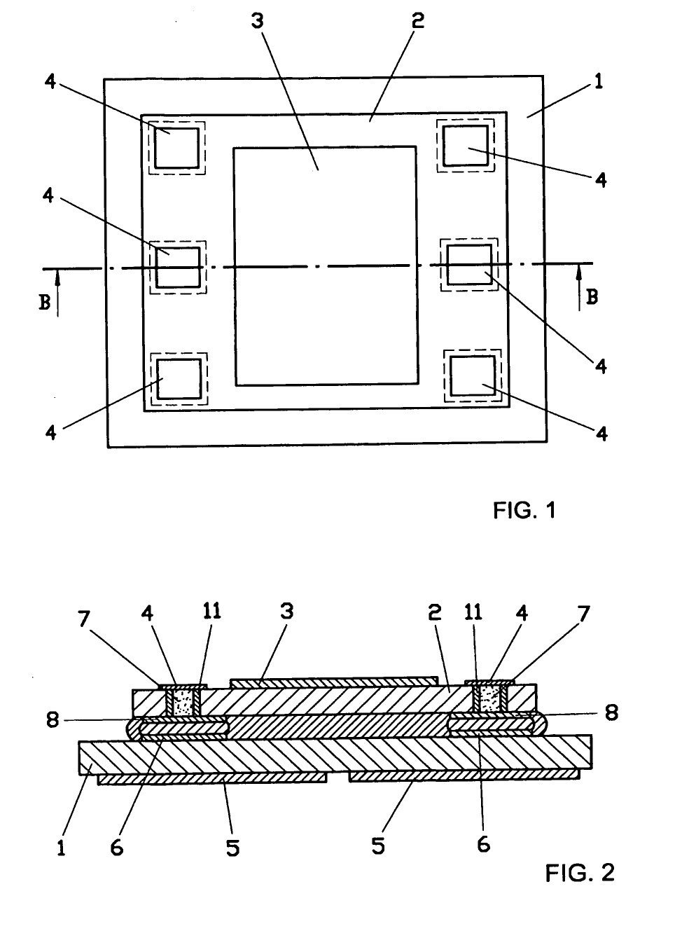

The chip module shown viewed from above in FIG. 1 features as its significant components a plate-shaped chip supporting body 1 as well as a sensor chip 2 positioned thereon. The sensor chip 2 is provided with an active sensor surface 3 on its upper side facing away from the chip supporting body 1, with the aid of which the sensor chip 2 embodied as a silicon semiconductor chip or ASIC can be used for fluidic applications. On the underside facing away from the chip supporting body 1 the sensor chip 2 possesses six contact pads 4 in the exemplary embodiment shown.

The overall structure of an exemplary embodiment of the chip module, corresponding to the embodiment variant of FIG. 1, can be taken from the cross-sectional view depicted in FIG. 2.

The chip supporting body 1 can again be seen in FIG. 2 which on its one flat side features a number of read/write contacts 5. These read/write contacts 5 are oriented in the installed state of the chip module in a sensor chip card towards the outside of the latter and are used for exchange of data with external chip card reader devices. On the side of the chip supporting body 1 facing away from the read/write contacts 5 there are a plurality of terminal panels 6, which are electrically connected to the read/write contacts 5 in a manner not shown in any greater detail here.

The sensor chip is placed and positioned on the chip supporting body 1 on the flat side provided with the terminal panels 6. The contact pads 4 as well as the sensor surface 3 can be seen on the underside of the sensor chip 2 facing away from the chip supporting body 1. It is evident in FIG. 2 as an embodiment of significance that the sensor chip 2 in the area of each of the contact pads 4 features an electrical signal line path 7, which is embodied from end to end as an electrical connection between the flat sides of the sensor chip 2, starting from the respective contact pad 4, to the opposite side. On the side lying opposite the contact pad the sensor chip 2 is provided with a contact panel 8 in each case. The contact panels 8 are to be found in the exemplary embodiment shown lying opposite the terminal panels 6 of the chip support carrier 1 in each case. Between the terminal panels 6 and the contact panels 8 as an electrical connection is located a solder bump 9 in each case which us also referred to as a bump. Between the surfaces of the sensor chip 2 and of the chip supporting body 1 pointing towards each other in the exemplary embodiment shown a so-called underfiller 10 is inserted as an attachment medium. The underfiller 10 is used for mechanical attachment of the sensor chip 2 on the chip supporting body 1.

The signal line path 7 for connecting the contact pads 4 to the contact panels 8, as can be seen from FIG. 2, is embodied such that the through hole inserted into the sensor chip 2 has on its inner side an annular coating 11 including a dielectric, for example a nitrate or an oxide compound, which provides an electrical isolation between the material of the sensor chip 2 and the internal signal line path 7. It is clear from the cross-sectional diagram that the installation height of the chip module formed from chip supporting body 1 and sensor chip 2 is essentially the same as the installation height of the individual elements. On the underside of the sensor chip 2 provided with the sensor surface 3 in this case, apart from the contact pads 4, there are no further components present which could restrict the surface extent of the sensor surface 3. This means that the sensor surface 3, by contrast with the solutions known from the related art, can occupy a significantly larger surface of the underside of the sensor chip 2.

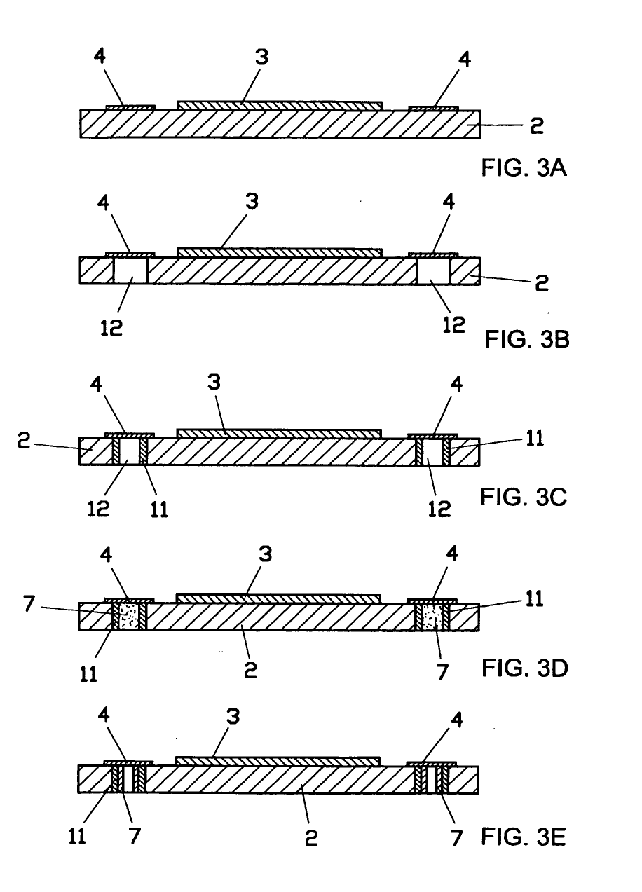

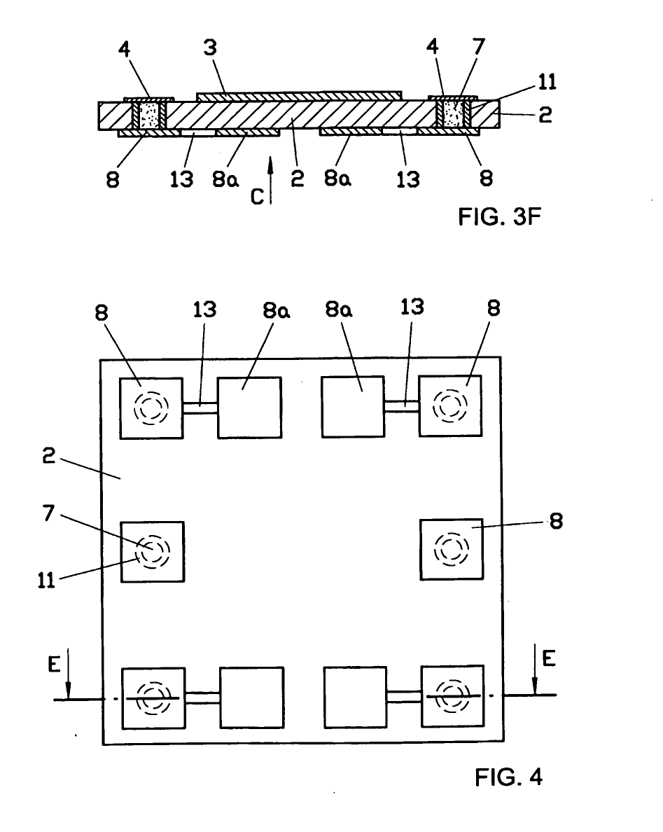

The individual production steps on the sensor chip 2 which are definitive for the embodiment of the chip module are shown in detail in the subsequent FIGS. 3A to 3F.

First of all the sensor chip 2 is provided in accordance with FIG. 3A in the manner known from the related art with the contact pads 4 and the sensor surface 3. It should be noted within the context of the production steps depicted that the sensor chips 2 are processed within the framework of a wafer arrangement.

Initially a cutout 12 in the sensor chip 2 is made using an anisotropic etching method, for example by a wet-chemical etching process or a plasma etching process. This cutout 12 runs from one flat side right through to the other, with the cutout 12 advantageously being embodied as a through-hole of round cross section.

Subsequently the inner surface of the cutout 12 is provided with an electrically-isolating coating 11, preferably in the form of a dielectric. The next step following this production step can be executed in accordance with FIG. 3D or 3E.

In FIG. 3D the entire inner space of the cutout 12 within the coating 11 is filled up with electrically-conductive material, so that an essentially round full cross section of the signal line path 7 is produced.

In the diagram in FIG. 3E by contrast the signal line path 7 is likewise embodied in an annular shape in the cross-section analogously to coating 11, so that a slight cavity remains inside the cutout 12.

Following on with the method, corresponding to FIG. 3D or 3E, the sensor chip 2 is provided on its flat side facing away from the contact pads 4 with the contact panels 8. The contact panels 8 in the exemplary embodiment shown in FIG. 3F are on the one hand arranged below the signal line path 7, but on the other hand additionally feature a conductor track 13 leading away sideways as well as a further contact panel 8a connected in each case with the conductor track 13. The position of the contact panels 8 and 8a as well as the conductor track 13 connecting these panels can be seen individually in the view from below of the sensor chip 2 in FIG. 4.

The position of the contact panels 8a or the fact that additional conductor tracks 13 and contact panels 8a are necessary in addition to the contact panels 8, depends on the terminal panels 6 on the chip supporting body 1 corresponding to the contact panels 8 or 8a.

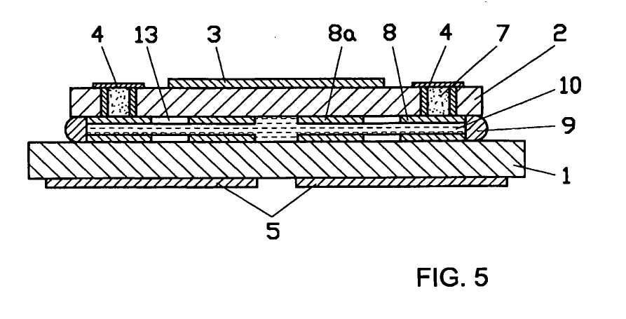

FIG. 5 is a cross-sectional diagram, corresponding to the cut lines E-E from FIG. 4, thus represents an additional embodiment variant to the cross-sectional diagram of the chip module already discussed from FIG. 2 of the chip module. The connection between the contact panels 8 or 8a and the terminal panels 6 on the chip supporting body 1 is again made by solder bumps 9. As an alternative to this electrical connection technique however the connection of the opposing terminal panels 6 to the contact panels 8 by a layer made from electrically-conductive adhesive is conceivable.

It goes without saying that the features of the chip module specified here, as well as the method described for the production of the chip module, are able to be used not only in the combination specified in each case, but also in other combinations or in isolation.

Overall, the chip module installation in sensor chip cards for fluidic applications proceeds with the flat side of the sensor chip oriented towards the chip supporting body and on which contact panels are arranged which are connected in each case to the contact pads located on the opposite flat side of the sensor chip by at least one electrical signal line path leading through the sensor chip and that the contact panels are connected to the terminal panels of the chip supporting body by electrically-conductive material.

This design enables both the active sensor surface 3 of the sensor chip 2 to be significantly enlarged, since all components which previously usually imposed restrictions on the corresponding flat side of the sensor chip 2 are dispensed with. Above and beyond this the installation height of the chip module is now essentially limited to the installation height of the major components sensor chip 2 and chip supporting body 1. Regarding the method, the described chip module can be produced at low cost, without the previous usual expensive process optimizations in manufacturing being necessary.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-14. (canceled)

15. A chip module for installing in sensor chip cards for fluidic applications, with connections to external chip card reader devices, comprising:
a chip supporting body having a plate-shape with a front flat side, oriented towards the sensor chip card, on which are arranged write/read contacts for data exchange with the external chip card reader devices and with a rear flat side, opposite the front flat side, on which are arranged terminal panels corresponding to and electrically-linked with the write/read contacts on the front flat side; and
a sensor chip having an underside on which are arranged contact pads and a flat side, opposite the underside and attached to the rear side of said chip supporting body, on which are arranged contact panels respectively connected to the contact pads by at least one signal line path leading through said sensor chip, the contact panels being connected to the terminal panels of said chip supporting body by electrically-conductive material.

16. The chip module as claimed in claim 15, wherein each of the at least one signal line path is constructed from an electrically-conductive inner track and a coating of electrically-isolating material surrounding the electrically-conductive inner track.

17. The chip module as claimed in claim 16, wherein each of the at least one signal line path has an annular cross-section.

18. The chip module as claimed in claim 16, wherein the electrically-isolating material in each of the at least one signal line path substantially fills the electrically-conductive inner track.

19. The chip module as claimed in 18, wherein the electrically-conductive inner track is made of a conductive adhesive.

20. The chip module as claimed in 18, wherein the electrically-conductive inner track is a metallic solder.

21. The chip module as claimed in 20, wherein the coating surrounding the electrically-conductive inner track is a dielectric.

22. A method for producing a chip module for installing in sensor chip cards for fluidic applications, with connections to external chip card reader devices, the chip module having a plate-shaped chip supporting body with a front flat side, oriented towards the sensor chip card, on which are arranged write/read contacts for exchange of data with the external chip card reader devices and having a rear side, opposite the front flat side, on which are arranged terminal panels corresponding and electrically connected to the write/read contacts, and a sensor chip, attached to the rear side of the chip supporting body, having contact pads electrically connected to the terminal panels of the chip supporting body, comprising:
forming on a wafer at least one chip supporting body provided with the write/read contacts and the terminal panels;
forming cutouts, running through the sensor chip between opposing flat sides, by an anisotropic etching process;
coating surface areas of the cutouts with an electrically-isolating material;
coating electrically-isolating material in the cutouts with an electrically-conducting material;
forming contact pads on a first flat side of the sensor chip;
applying contact panels to a second flat side of the sensor chip; and
subsequent to said coating, forming and applying, attaching the second flat side of the sensor chip to the rear side of the chip supporting body and establishing an electrical connection between the contact panels of the sensor chip and the terminal panels of the chip supporting body.

23. The method for producing a chip module as claimed in claim 22, wherein the anisotropic etching process is a wet chemical process.

24. The method for producing a chip module as claimed in claim 22, wherein the anisotropic etching process is a plasma etching process.

25. The method for producing a chip module as claimed in 24, wherein the electrically-isolating material is a dielectric.

26. The method for producing a chip module as claimed in 25, wherein said establishing of the electrical connection between the contact panels of the sensor chip and the terminal panels of the chip supporting body includes a soldering process.

27. The method for producing a chip module as claimed in 25, wherein said establishing of the electrical connection between the contact panels of the sensor chip and the terminal panels of the chip supporting body includes applying a conductive adhesive.

28. The method for producing a chip module as claimed in 27, further comprising after said establishing of the electrical connection between the contact panels of the sensor chip and the terminal panels of the chip supporting body, filling remaining space between the second flat side of the sensor chip and the rear side of the chip supporting body with an underfiller.
